(19) United States
(12) Patent Application Publication
(10) Pub. No.: US 2020/0144799 A1
(43) Pub. Date: May 7, 2020

(54) MULTI-SHAPED ELECTRICAL CONDUIT SYSTEM AND COMPONENTS THEREOF

(71) Applicant: Safran Landing Systems Canada Inc., Ajax (CA)

(72) Inventor: Marianna Lakerdas, Ajax (CA)

(73) Assignee: Safran Landing Systems Canada Inc., Ajax, ON (CA)

(21) Appl. No.: 16/182,068

(22) Filed: Nov. 6, 2018

(51) Int. Cl. H02G 3/04; H05K 9/00; H02G 3/30; B33Y 80/00; B33Y 10/00; B33Y 50/02

(52) U.S. Cl. CPC H02G 3/0487; H05K 9/0098; H02G 3/30; B29C 64/118; B33Y 80/00; B33Y 10/00; B33Y 50/02; H02G 3/0437

(57) ABSTRACT

Several examples are provided that relate to components or component parts of an electrical harness, such as an electrical conduit, for routing electrical signals to an electromechanical actuator. These components may benefit from additive manufacturing techniques or methodologies. In these examples, the component parts can have non-standard shapes and sizes, as well as one or more additional beneficial attributes, such as shielding properties, anti-chafing properties, reduced weight, integral attachment interfaces, condensation drainage holes, etc. Some embodiments of the present disclosure may be suitably manufactured with any powder bed or direct deposition technology using the melting of rods/wire/powder, such as selective laser sintering (SLS). Other Solid Freeform Fabrication (SFF) technology, such as Fused Deposition Modeling (FDM) technology, can be employed to manufacturer one or more components parts of the present disclosure. In some embodiments, the representative methods include optional post-machining, post-treatments, etc.

### BACKGROUND

Many systems are provided aboard vehicles, such as aircraft, that consist of moving mobile parts. Wing elements (for example an aileron, a flap, an air brake), elements of the thrust reversers, elements of a propeller pitch driving mechanism (for example on an helicopter or a turboprop engine), etc., are just a few of such mobile parts.

Mobile parts are associated with other aircraft systems. For example, most aircraft are equipped with landing gear that enables the aircraft to travel on the ground during takeoff, landing and taxiing phases. This landing gear comprises several wheels which may be arranged according to configurations varying from one aircraft to the other. These wheels can be braked via movement of a plunger that slides relative to brake friction members. Further, some landing gear may be retracted inside the wings or the fuselage of the aircraft to decrease air drag on the aircraft during flight phases. In these systems, a landing gear strut, for example, is movable between an extended position and a retracted position.

On modern aircrafts, more and more electromechanical actuators are used to implement such mobile parts. In fact, the advantages of using electromechanical actuators are numerous: simple electric distribution and driving, flexibility, simplified maintenance operations, etc. Generally, an electromechanical actuator comprises a mobile actuating member which moves the mobile part, an electric motor intended to drive the mobile actuating member and thus the mobile part, and one or more sensor(s) for sensing various parameters of the electromechanical actuator.

The electric motor and the one or more sensors require electrical communication via wires. These wires are conventionally routed through wire harnesses comprising corrosive resistance steel (CRES) rigid tubing. However, with the use of CRES tubing in current electromechanical actuator architecture, harness signal separation has become an issue. For example, power and signal wires require physical separation to avoid “noisy” power supply signals from interfering with sensitive signals. CRES rigid tubing does not allow for such signal separation, as all wires in one system are routed in the same conduit. To minimize noise interference with CRES tubing, additional shielding must be added to the wires, thereby increasing bundle diameter and system weight. With this solution, however, system noise may never be fully reduced. Additionally, CRES tubing is limited in size, shape, bend radii, and uses old manufacturing technology. Also with CRES tubing, current attachment methods limit the flexibility of design installation solutions.

### SUMMARY

In accordance with an aspect of the present disclosure, a component, such as an electrical conduit, is provided. The electrical conduit comprises a conduit body comprised of two or more body sections, and two or more passageways extending through at least one of the two or more body sections. The two or more passageways are separated within the body by at least one partition, wherein the at least one partition exhibits electrical shielding properties.

In an embodiment, the at least one partition is constructed of or plated with a metal material in order to exhibit electrical shielding properties.

In an embodiment, the two or more body sections include a first body section and a section body section.

In this or other embodiments, the first body section is disposed at a non-standard angle with respect to the second body section. In this or other embodiments, the non-standard angle does not form a planar 2-dimensional bend. In some embodiments, the non-standard angle is not 15 degrees or a multiple of 15 degrees.

In an embodiment, the first or second body section includes an integral attachment interface. In some embodiments, the integral attachment interface includes one or more attachment lugs. Additionally or alternatively, the integral attachment interface includes first and second rib members spaced apart and extending along a portion of either the first section or the second section.

In an embodiment, the electrical conduit further comprises a power wire routed through one of the two or more passageways, the power wire configured to carry a power signal, and a sensor wire routed through the other one of the two or more passageways, the sensor wire configured to carry a sensed signal.

In accordance with another aspect of the present disclosure, a method is provided for making a component part of an electrical harness system. The method comprises: obtaining digital data associated with the component part, the digital data representative of a body having at least one passageway; and using the digital data to fabricate the component form a first material by a solid freeform fabrication process.

In an embodiment, the solid freeform fabrication process is Fused Deposition Modeling and the first material includes PEKK.

In an embodiment, the at least one passageway includes first and second passageways extending through a section of the component part and separated by a partition, and wherein the method further comprises plating or coating at least a portion of the partition with an electrically shielding material. In some embodiments, the electrically shielding material includes nickel, zinc or copper.

In an embodiment, the method further comprises routing a power wire through one of the two or more passageways, the power wire configured to carry a power signal; and routing a sensor wire through the other one of the two or more passageways, the sensor wire configured to carry a sensed signal.

In an embodiment, the digital data is further representative of at least one attachment structure. In some embodiments, the attachment structure is selected from a group consisting of: one or more attachment lugs; and first and second rib members spaced apart and extending traverse along a portion of the body.

In an embodiment, the digital data is further representative of the body having first and second sections, and wherein the first section is disposed at a non-standard angle with respect to the second section. In some embodiments, the non-standard angle includes angles that are not a multiple of 15 degrees.

In accordance with another aspect of the present disclosure, a computer readable medium is provided having a computer executable component comprising CAD data to enable the fabrication of a component of an electrical harness utilizing a solid freeform fabrication process.

This summary is provided to introduce a selection of concepts in a simplified form that are further described below in the Detailed Description. This summary is not intended to identify key features of the claimed subject matter, nor is it intended to be used as an aid in determining the scope of the claimed subject matter.

### DESCRIPTION OF THE DRAWINGS

The foregoing aspects and many of the attendant advantages of the claimed subject matter will become more readily appreciated as the same become better understood by reference to the following detailed description, when taken in conjunction with the accompanying drawings, wherein:

FIG. 1 is a representative embodiment of a component, such as an electrical conduit, formed in accordance with one or more aspects of the present disclosure, which can be part of an electrical harness for use in an electrical system that employs electromechanical actuators;

FIGS. 2A and 2B are cross-sectional views of the electrical conduit of FIG. 1 taken along lines 2A-2A and 2B-2B in FIG. 1;

FIG. 3 is a side view of the conduit of FIG. 1;

FIG. 4 is another representative embodiment of an electrical conduit formed in accordance with one or more aspects of the present disclosure;

FIG. 5 depicts an electrical conduit assembly comprised of the electrical conduit of FIG. 1 having a number of wires routed therethrough as well as having at least one connection interface;

FIG. 6 depicts the conduit assembly of FIG. 5 attached to a structural member via a clamp;

FIG. 7 depicts the conduit assembly of FIG. 5 connected to another harness component, such as a junction box, via the connection interface;

FIG. 8 is a flow chart depicting a representative example of a method for forming a component, such as the conduit shown in FIG. 1 or FIG. 4, in accordance with aspects of the present disclosure; and

FIG. 9 is a block diagram depicting one example of an environment for carrying out the method of FIG. 8.

### DETAILED DESCRIPTION

The detailed description set forth below in connection with the appended drawings, where like numerals reference like elements, is intended as a description of various embodiments of the disclosed subject matter and is not intended to represent the only embodiments. Each embodiment described in this disclosure is provided merely as an example or illustration and should not be construed as preferred or advantageous over other embodiments. The illustrative examples provided herein are not intended to be exhaustive or to limit the claimed subject matter to the precise forms disclosed.

In the following description, specific details are set forth to provide a thorough understanding of exemplary embodiments of the present disclosure. It will be apparent to one skilled in the art, however, that the embodiments disclosed herein may be practiced without embodying all of the specific details. In some instances, well-known process steps have not been described in detail in order not to unnecessarily obscure various aspects of the present disclosure. Further, it will be appreciated that embodiments of the present disclosure may employ any combination of features described herein.

The following description provides several examples that relate to components or component parts of an electrical harness, such as an electrical conduit, for routing electrical signals to an electromechanical actuator. In some embodiments, these components can benefit from additive manufacturing techniques or methodologies. In these examples, the component parts can have non-standard shapes and sizes, as well as one or more additional beneficial attributes, such as shielding properties, anti-chafing properties, reduced weight, integral attachment interfaces, condensation drainage holes, etc. Some embodiments of the present disclosure may be suitably manufactured with any powder bed or direct deposition technology using the melting of rods/wire/powder, such as selective laser sintering (SLS). Other Solid Freeform Fabrication (SFF) technology, such as Fused Deposition Modeling (FDM) technology, can be employed to manufacturer one or more components parts of the present disclosure. In some embodiments, the representative methods include optional post-machining, post-treatments, etc.

Some embodiments of the present disclosure may reference components or component parts suitable for use in aircraft. However, it will be appreciated that aspects of the present disclosure transcend any particular vehicle type or industry, and any reference to aircraft or the like is only representative, and therefore, should not be construed as limiting the scope of the claimed subject matter.

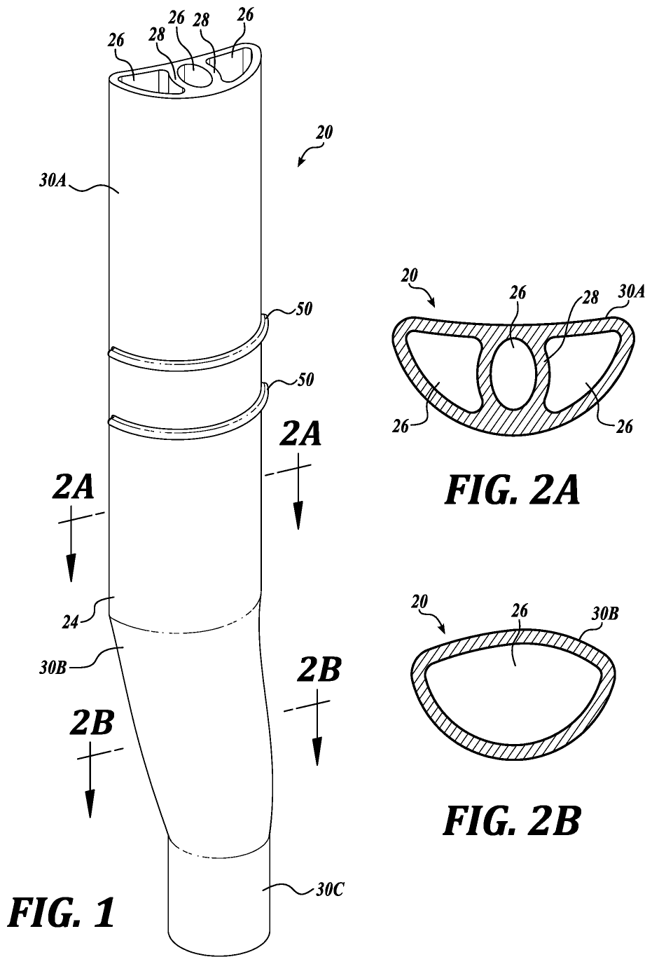

Turning now to FIG. 1, there is shown one representative embodiment of a component part, such as an electrical conduit 20, suitable for use in an electrical harness and formed in accordance with one or more aspects of the present disclosure. As shown in FIG. 1, the electrical conduit 20 includes a multi-lumenal conduit body 24. In other words, the electrical conduit 20 includes or is formed with a plurality of lumens or passageways 26 separated by one or more partitions 28. The electrical conduit 20 in some embodiments is rigid and extends a predetermined length.

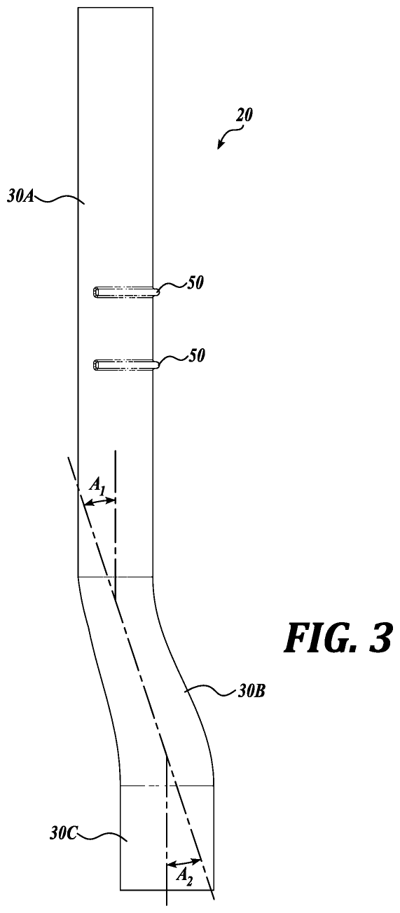

The electrical conduit 20, or parts thereof, can have any shape, cross-section or configuration, which will depend on its intended application. For example, the conduit can include any number of passageways 26 (e.g., 1-N). These passageways can have any cross-sectional shape and extend the entirety of the conduit 20 or sections thereof (see, e.g., FIGS. 2A and 2B). In embodiments with multiple passageways 26, the partitions 28 may take any shape or thickness. The shape, cross-section and/or configuration of the conduit can be constant along its length or sections thereof. In other embodiments, the shape, cross-section and/or configuration of the conduit can vary along its length or sections thereof.

In some embodiments, the cross sectional shape of the conduit is generally constant along its predetermined length or sections thereof. For example, referring to FIGS. 1 and 2A, the body section 30A of the conduit 20 may have a general crescent shaped cross section. Such a shape can be beneficial by cooperating with the shape of a structural member (e.g., cylindrical shaft) to which it is mounted, thereby providing a closer coupling to the structural member. Other cross sectional shapes are contemplated in embodiments of the present disclosure, which do or do not beneficially cooperate with other structural members of the installation environment.

In other embodiments, the cross sectional shape of the conduit 20 remains constant along its length but can vary in cross sectional area along its length, or sections thereof. In some, the cross-section shape of the conduit 20 may vary along the conduit or parts thereof, or may vary along one or more sections, such as sections 30A and 30B shown in FIGS. 1 and 2A-2B. In other embodiments, the cross-sectional size of the conduit 20 stays constant as it extends from one end to the other. Of course, the cross-sectional configuration of conduit 20 can be either asymmetrical or symmetrical, or symmetrical in one or more sections and asymmetrical in one or more sections.

In some embodiments, the electrical conduit 20 can extend in a linear manner along its predetermined length. In other embodiments, like that shown in FIG. 1, the conduit can have two or more sections 30A-30C that are at an angle to one another. In other words, the conduit may include one or more “bends.” Reference to “bend” in this manner is not intended to mean a physical deformation or formation of the component, but only to describe a non-linear configuration along the length of the conduit. As shown in FIG. 3, in some embodiments, the angle A₁ created between sections 30A and 30B and/or angle A₂ between 30B and 30C may be compound and non-standard (i.e., planar 2 dimensional bends). Such non-standard angles between sections of the conduit provide flexibility in placement, application, etc. For example, a section of the conduit can be formed at any non-standard angles between junction boxes, or between a junction box and a terminal part, such as an electric motor, computer system, etc.

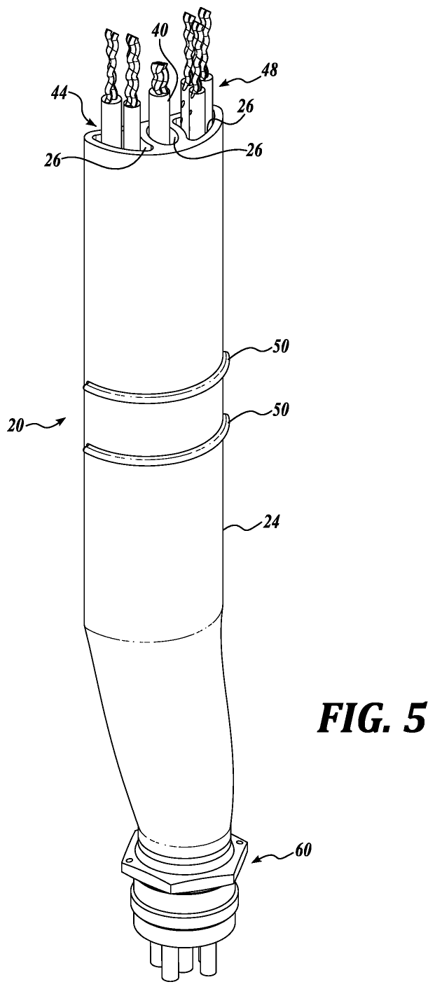

Referring now to FIG. 5, there is shown one or more wires, configured to carry electrical signals, routed through one or more passageways 26 of the conduit 20. In the embodiment shown in FIG. 5, wires 40 are configured to carrying electrical power to, for example, an electrical motor (not shown), wires 44 are configured to carry sensor signals, such as position signals, and wires 48 are configured to carry temperature signals from another electrical component, such as a thermocouple, or the like. Other wires may be additionally or alternatively routed through one of the passageways. For example, wires, such as wires that carry control signals, can be routed in a passageway that is separate from the passageway carrying the power wire(s).

In some embodiments, one or more partitions 28 may include or are formed with electrical shielding properties to shield electrical interference associated with the power carried on wires 40 from the non-power signals carried on wires 44 and/or 48. In this regard, the conduit or sections, parts, or portions thereof can be configured to reduce or eliminate interference from noisy power, etc. In some embodiments, the partitions 28 can be constructed out of or can be plated or otherwise coating with conductive or magnetic material to provide shielding. In one embodiment, the one or more partitions 28 are nickel, zinc, or copper plated along surfaces that separate the wires 40 from the wires 44 and 48. Other surfaces of the conduits, such as the inner surfaces of one or more passageways can be plated or otherwise coated with nickel or zinc to provide both shielding and against electromagnetic interference (EMI) and/or high intensity radiated fields (HIRF) protection. In some embodiments, the exterior surface of the component part is constructed out of, plated or otherwise coated with a conductive material, such as zinc or nickel, to provide, for example, protection against electromagnetic interference (EMI) and high intensity radiated fields (HIRF).

In these or other embodiments, one or more surfaces of the component or component part, or portions thereof, can be additionally or alternatively constructed out of or coated with an anti-friction material, such as PTFE. For example, PTFE can be applied to the outer mating surface of the conformal conduit. This aims to mitigate any possible abrasion effects, on both the structure to which it is attached and the conduit, due to vibration. In these or other embodiments, PTFE can be applied to any internal surface of the conduit to achieve better wire pull-through and to mitigate the vibration effects of wires fretting against the inside of the conduit. In yet other embodiments, the wires 40, 44, and 48 can be signal or double shielded wires, and may include in these or other embodiments an anti-friction braided jacket.

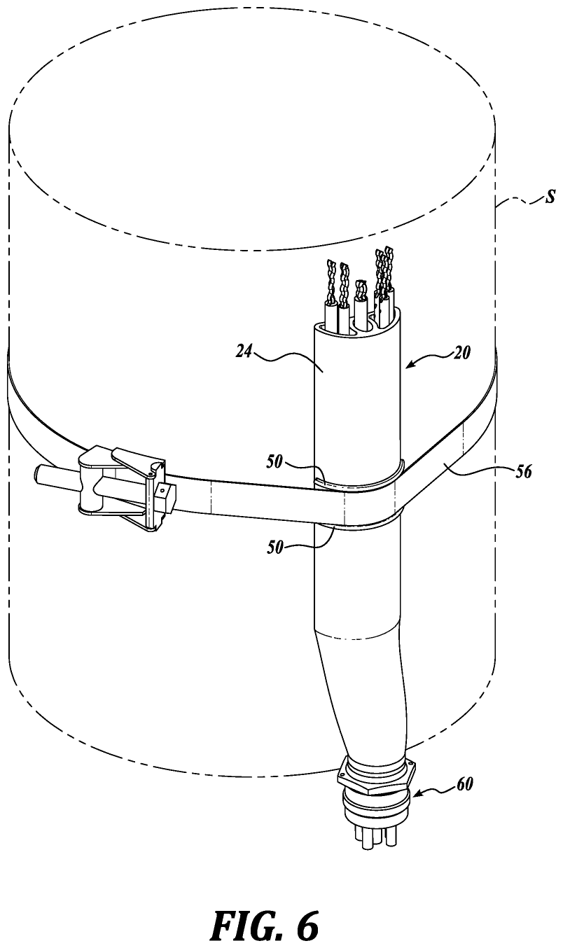

FIG. 6 illustrates the electrical conduit 20 of FIG. 1 attached to a structural member S (e.g., shock strut, main fitting, trailing arms, truck beam, actuators, side and drag braces, etc.) in accordance with one embodiment of the present disclosure. In the embodiment shown in FIG. 6, the electrical conduit 20 can include or be integrally formed with a pair of ribs 50 or other attachment locators positioned along the length of the electrical conduit 20. As shown in FIG. 6, the ribs 50 are configured and arranged so as to cooperate with a band clamp 56 for mounting to the structural member S. In use, the ribs 50 ensure against possible migration of the conduit and band clamp from vibrational forces, etc., and provide easy repeatability of the attachment location of the conduit.

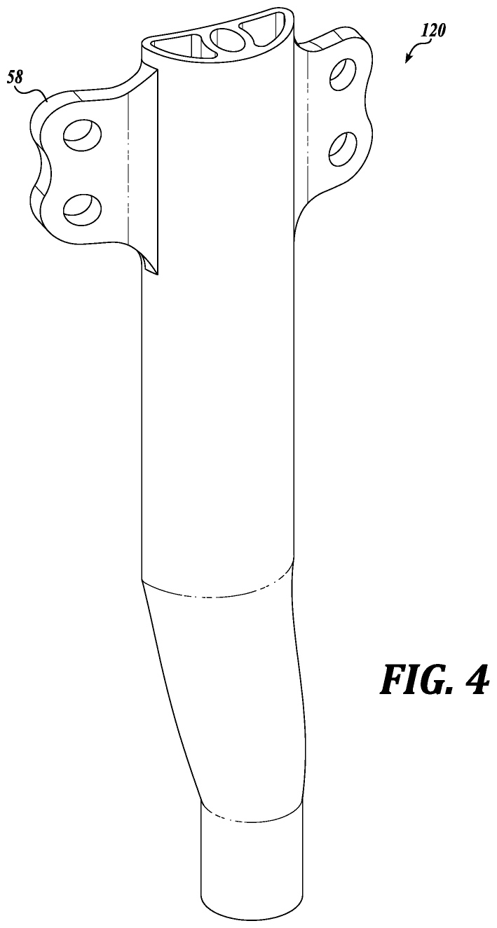

Of course, other structure may be employed to aid in the attachment of the electrical conduit to the structural member S. For example, a conduit 120 can include or be integrally formed with one or more pairs of attachment lugs 58, as shown in FIG. 4. Other embodiments are possible. For example, the electrical conduit may include attachment lugs 58 (see FIG. 4) at one end and ribs 50 (see FIG. 5) at the other end for attachment to the structural member S. Of course, depending on the length of the conduit, more than one set of ribs, attachment lugs, etc., can be employed to attach the conduit to one or more structural members.

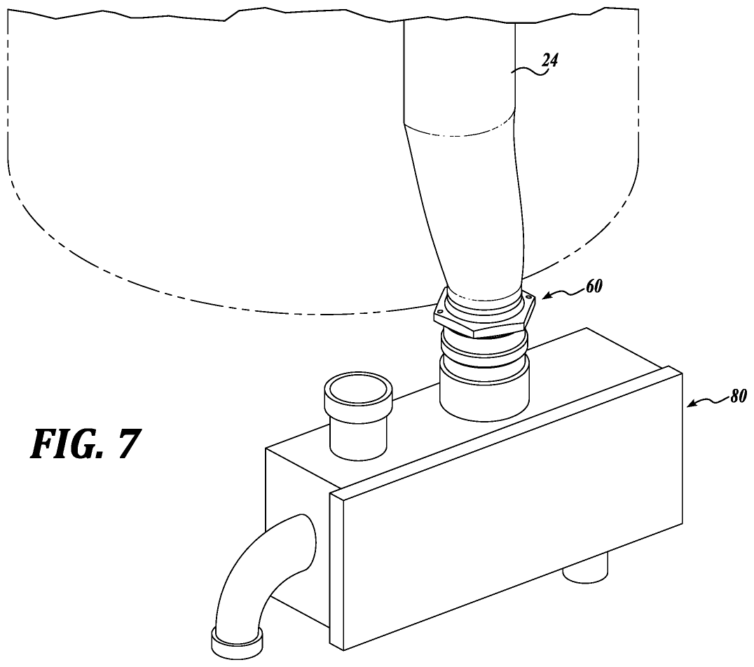

When installed, the electrical conduit extends between two junction boxes or flexible conduits, between a terminal end, such as a computer, electrical component, or electrical motor, and a junction box, among others. In that regard, the electrical conduit, such as conduit 20, can be fitted with one or more standard fittings or the like so as to provide a suitable connection interface 60. In the embodiment shown, the connection interface 60 includes a spin coupler. Other fittings or connection interfaces may be practiced with embodiments of the present disclosure. In one embodiment, the connection interface 60 is configured to interface with a standard junction box 80, as shown in FIG. 7. In other embodiments, the connection interface 60 can be configured to interface with a custom configured junction box, which can designed and fabricated according to one or more aspects of the present disclosure.

According to aspects of the present disclosure, any component or component part, such as the electrical conduit 20, the electrical conduit 120, the junction box 80, and/or any related accessories such as angled adaptors that no longer must be standard angles (i.e., not any multiple of 15 degrees, including 15 degrees, 30 degrees, 45 degrees, 60 degrees, 75 degrees, or 90 degrees), may be fabricated by additive manufacturing (AM) techniques. Conventionally, rigid conduits have been heretofore fabricated by traditional metal extrusion techniques, casting techniques, or metal forming techniques. In one aspect of the present disclosure, an alternative fabrication technique or methodology is provided wherein the component part, such as the conduit 20, junction box 80, etc., is fabricated layer by layer via the process of direct metal laser sintering, selective laser melting (SLS), Fused Deposition Modeling (FDM), or a similar form of additive manufacturing, depending, for example, on material selection, desired properties of the finished part, the part's intended application, etc. Embodiments of these components parts can be fabricated as described below. Other embodiments of the component parts can be fabricated with any conventional process, such as extrusion, casting, metal forming, etc.

In some embodiments of the present disclosure, the component or component part, such as conduit 20, conduit 120, junction box 80, etc., is fabricated out of thermoplastic, employing fused deposition modeling techniques. Generally described, fused deposition modeling techniques employ a fused deposition modeling system to build a 3D part or model from a digital representation of the 3D part in a layer-by-layer manner by extruding a flowable part material. The part material is extruded through an extrusion tip carried by an extrusion head, and is deposited as a sequence of roads on a substrate in an x-y plane. The extruded part material fuses to previously deposited modeling material, and solidifies upon a drop in temperature. The position of the extrusion head relative to the substrate is then incremented along a z-axis (perpendicular to the x-y plane), and the process is then repeated to form a 3D part resembling the digital representation.

Movement of the extrusion head with respect to the substrate is performed under computer control, in accordance with build data that represents the 3D part. The build data is obtained by initially slicing the digital representation of the 3D part into multiple horizontally sliced layers. Then, for each sliced layer, the host computer generates a build path for depositing roads of modeling material to form the 3D part.

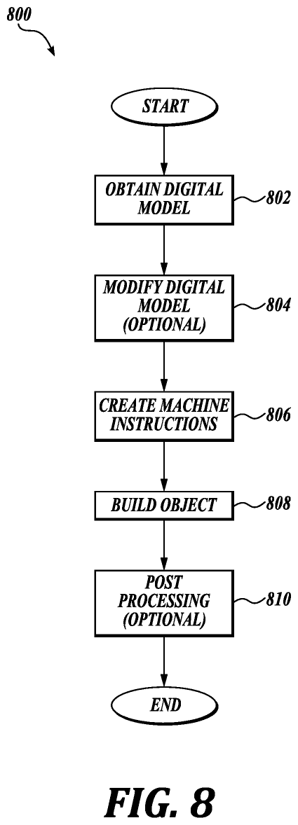

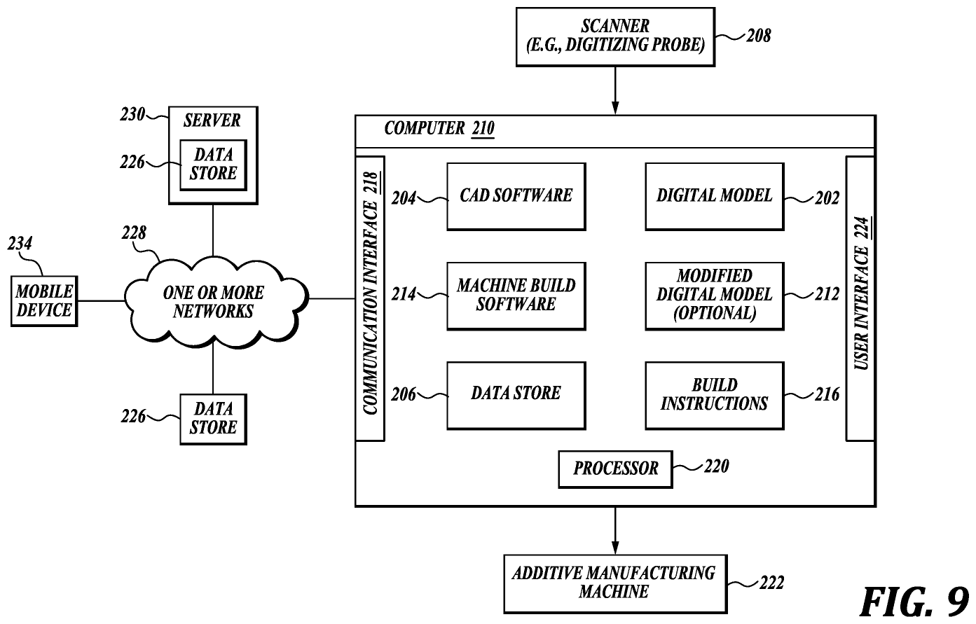

FIG. 8 is a block diagram illustrating a representative fabrication process of a component part having a plurality of passageways and partitions, such as conduit 20. FIG. 9 is a block diagram depicting one environment, including one or more components of a system, used to carry out the one or more processes of the method set forth in FIG. 8. As can be seen in FIG. 8, the first step in the process is obtaining, at block 802, a digital model 202 (see FIG. 9), such as a Computer Aided Design (CAD) solid model or CAD surface model, of an object to be fabricated, such as conduit 20. In some embodiments, the digital model includes graphical 2D or 3D data representing the object to be fabricated.

The digital model 202 at block 802 may be obtained in a number of ways. For example, the digital model 202 may be obtained by generating a solid model of the conduit and/or surface model of the inner surfaces of the passageways within CAD software 204 (see FIG. 9). In other embodiments, the digital model 202 may be obtained from a data store, such as data store 206 of the computer 210, which stores one or more CAD models of component parts, such as conduits, junction boxes, etc., for various applications, such as landing gear for a BOEING® 737, BOEING® 777, BOEING® 787, AIRBUS® 320, AIRBUS® 330, BOMBARDIER® C Series or Q Series aircraft, EMBRAER® E195, just to name a few. It will be appreciated that the digital model 202 may be obtained from other data stores, such as a data store 226 associated with either a local or remote server 230 or cloud based storage solution. Such communication with these data stores 226 is facilitated by communications interface 218 through one or more networks 228.

In other embodiments, the digital model 202 may be obtained by scanning a previously fabricated component part, a prototype of the component part made from clay modeling, etc., and inputting the scanned data into a suitable CAD program, such as CAD software 204. For example, a component part may be scanned (e.g., measured) using a digitizing probe 208 that traverses the surfaces of the component part to generate suitable 2 and 3 dimensional data indicative of the geometry thereof.

In yet other embodiments, the digital model 202 can be created in a CAD system with the use of computer 210 and CAD software 204. The design can be general to very detailed, but generally includes design details such as external shape and size of the part, internal passage size and location, cross-sectional shape along the conduit, and the like. In some embodiments, the digital model includes graphical data representative of the conduit 20 or conduit 120.

Once the digital model 202 of the component part is obtained, the method 800 continues to block 804, where the digital model 202 can be viewed and optionally manipulated by the computer 210 within CAD software 204. For example, at block 204, the CAD technician or the like can interactively modify the digital model 202 via the CAD software 204 in order to alter the geometry of one or more portions of the component part, aiming for improved characteristics, modifications for a custom or new installation, etc. In some embodiments, the modified digital model 204 includes graphical data representative of the conduit 20 or conduit 120.

Examples of suitable CAD software that be employed for carrying out aspects of some embodiments of the present disclosure include but are not limited to Solid Works, Pro-E, CATIA, etc. Once obtained and/or modified, the digital model 202 or modified digital model 212 (optional) can be saved, for example, to system memory, such as the data store 206, and/or associated memory, such as data store 226 from a local or remote server 230 or a cloud based storage solution.

Once the CAD design of the part is created, the conduit can then be fabricated, using any additive manufacturing process, such as fused deposition modeling (FDM), stereolithography (SLA), selective laser sintering (SLS), among others, with an additive manufacturing machine 222. In one embodiment, the component part, such as conduit 20, is fabricated by an FDM apparatus. In some embodiments, the fabricated component part is rigid based on the materials employed.

The additive manufacturing machine 222, such as an FDM apparatus, is utilized to fabricate the component part in three dimensions on a bed, such as a fixtureless platform, from a CAD data file, such as the digital model 202 or modified digital model 204. In order for the an additive manufacturing machine 222 to fabricate the component part in some embodiments, the CAD data file, such as the digital model 202 or modified digital model 204, may need to be translated into suitable machine instructions. Accordingly, at block 806 of the method 800, the digital model 202 or modified digital model 204 is processed for compatibility with the manufacturing system, including the additive manufacturing machine 222. In an embodiment of the present disclosure, a surface file (also known as a .stl file) is created from the either the digital model 202 or the modified digital model 204, depending on which is being used to fabricate the component part. The surface file conversion allows the manufacturing system to read CAD data from any one of a variety of CAD systems, such as CAD software 204 running on computer 210. In some embodiments, processing of the CAD data file (e.g., digital model 202, modified digital model, etc.) can be carried out by the computer 210, the additive manufacturing apparatus 222 or a combination of the computer 210 and the additive manufacturing apparatus 222.

It will be appreciated that the CAD data files or surface files may be stored on a computer-readable medium either associated with the CAD system, the manufacturing system or a networked or cloud based storage solution. For example, computer-readable media can be any available media that can be accessed by the computer 210 or the computer 210 and/or the additive manufacturing apparatus 222. By way of example, and not limitation, computer-readable media may comprise computer storage media and communication media. Computer storage media includes volatile and nonvolatile, removable and non-removable media implemented in any method or technology for storage of information such as computer readable instructions, data structures, program modules or other data.

In some embodiments, this surface file is then converted into cross-sectional slices or slice files, where each slice can be uniquely defined about its build strategy by varying the tool path of the machine 222, such as an FDM apparatus. FDM is an additive process that uses a layered manufacturing approach to fabricate three-dimensional objects on a fixtureless platform from its CAD data file. For a more detail description of an FDM process, see U.S. Pat. Nos. 5,121,329 and 5,340,433, the disclosures of which are incorporated herein by reference.

Once suitable machine instructions are created (if needed), such as the surface and/or slice files, at block 806, these machine instructions are then used by the additive manufacturing machine 222 to build the object or component part at block 810. In one embodiment, a FDM apparatus is used to carry out the machine instructions. In this regard, a filament of the desired material passes through a heated liquefier. In some embodiments, the desired material is selected from a group consisting of thermoplastics. In some embodiments, the thermoplastics includes a class of thermoplastics comprising polyetherketoneketone (PEKK), such as Antero 800NA from Stratasys Direct Manufacturing. Other materials include Certified Ultem 9085 Resin, 3D printed CRES, or any suitable metallic material.

The liquefier melts the material and extrudes a continuous bead, or road, of material through an extrusion tip carried by an extrusion head and deposits the material on a fixtureless platform. The liquefier movement is computer controlled along the X and Y directions, based on the build strategy of the part to be manufactured and represented in the CAD data file. When deposition of the first layer is completed, the fixtureless platform indexes down, and the second layer is built on top of the first layer. This process continues in computer control until the part manufacturing is completed.

After the object, such as the component or component part, is built at block 808, one or more post processing steps can be optionally carried out at block 810. For example, the passageways of the conduits or other surfaces can be deburred or otherwise smoothed, as needed. In some embodiments, after the conduit is fabricated, it may be plated or otherwise coated with a conductive or magnetic material. In one embodiment, one or more surfaces of the component or component part, such as conduit 20 or conduit 120, is plated or coated, for example, with nickel, zinc or copper. In embodiments that manufacture the component or component part out of metal, nickel, zinc or copper plating or coatings may be applied in some embodiments and omitted in others. In these or other embodiments, the post processing steps can additionally or alternatively include plating or otherwise coating one or more surfaces of the component or component part, such as conduit 20 or conduit 120, with an anti-friction material, such as PTFE. In some embodiments, the anti-friction coating can be subsequently applied via suitable processes to the metal plating or coating.

As described above, one or more aspects of the method are carried out in a computer system. In this regard, a program element is provided, which is configured and arranged when executed on a computer for fabricating the component part, such as the conduit 20. The program element may specifically be configured to perform the steps of: obtaining digital data associated with the component part, the digital data representative of a body having at least one passageway; and using the digital data to fabricate the component form a first material by a solid freeform fabrication process.

The program element may be installed in a computer readable storage medium. The computer readable storage medium may be any one of the computing devices, control units, etc., described elsewhere herein or another and separate computing device, control unit, etc., as may be desirable. The computer readable storage medium and the program element, which may comprise computer-readable program code portions embodied therein, may further be contained within a non-transitory computer program product.

As mentioned, various embodiments of the present disclosure may be implemented in various ways, including as non-transitory computer program products. A computer program product may include a non-transitory computer-readable storage medium storing applications, programs, program modules, scripts, source code, program code, object code, byte code, compiled code, interpreted code, machine code, executable instructions, and/or the like (also referred to herein as executable instructions, instructions for execution, program code, and/or similar terms used herein interchangeably). Such non-transitory computer-readable storage media include all computer-readable media (including volatile and non-volatile media).

In one embodiment, a non-volatile computer-readable storage medium may include a floppy disk, flexible disk, hard disk, solid-state storage (SSS) (e.g., a solid state drive (SSD), solid state card (SSC), solid state module (SSM)), enterprise flash drive, magnetic tape, or any other non-transitory magnetic medium, and/or the like. A non-volatile computer-readable storage medium may also include a punch card, paper tape, optical mark sheet (or any other physical medium with patterns of holes or other optically recognizable indicia), compact disc read only memory (CD-ROM), compact disc compact disc-rewritable (CD-RW), digital versatile disc (DVD), Blu-ray disc (BD), any other non-transitory optical medium, and/or the like. Such a non-volatile computer-readable storage medium may also include read-only memory (ROM), programmable read-only memory (PROM), erasable programmable read-only memory (EPROM), electrically erasable programmable read-only memory (EEPROM), flash memory (e.g., Serial, NAND, NOR, and/or the like), multimedia memory cards (MMC), secure digital (SD) memory cards, SmartMedia cards, CompactFlash (CF) cards, Memory Sticks, and/or the like. Further, a non-volatile computer-readable storage medium may also include conductive-bridging random access memory (CBRAM), phase-change random access memory (PRAM), ferroelectric random-access memory (FeRAM), non-volatile random-access memory (NVRAM), magnetoresistive random-access memory (MRAM), resistive random-access memory (RRAM), Silicon-Oxide-Nitride-Oxide-Silicon memory (SONOS), floating junction gate random access memory (FJG RAM), Millipede memory, racetrack memory, and/or the like.

In one embodiment, a volatile computer-readable storage medium may include random access memory (RAM), dynamic random access memory (DRAM), static random access memory (SRAM), fast page mode dynamic random access memory (FPM DRAM), extended data-out dynamic random access memory (EDO DRAM), synchronous dynamic random access memory (SDRAM), double data rate synchronous dynamic random access memory (DDR SDRAM), double data rate type two synchronous dynamic random access memory (DDR2 SDRAM), double data rate type three synchronous dynamic random access memory (DDR3 SDRAM), Rambus dynamic random access memory (RDRAM), Twin Transistor RAM (TTRAM), Thyristor RAM (T-RAM), Zero-capacitor (Z-RAM), Rambus in-line memory module (RIMM), dual in-line memory module (DIMM), single in-line memory module (SIMM), video random access memory VRAM, cache memory (including various levels), flash memory, register memory, and/or the like. It will be appreciated that where embodiments are described to use a computer-readable storage medium, other types of computer-readable storage media may be substituted for or used in addition to the computer-readable storage media described above. In some embodiments, the data store 206 and/or data store(s) 226 can comprise one or more of the computer readable storage media.

As should be appreciated, various embodiments of the present disclosure may also be implemented as methods, apparatus, systems, computing devices, computing entities, and/or the like, as have been described elsewhere herein. As such, embodiments of the present disclosure may take the form of an apparatus, system, computing device, computing entity, and/or the like executing instructions stored on a computer-readable storage medium to perform certain steps or operations. However, embodiments of the present disclosure may also take the form of an entirely hardware embodiment performing certain steps or operations.

Various embodiments are described above with reference to block diagrams and flowchart illustrations of apparatuses, methods, systems, and computer program products. It should be understood that each block of any of the block diagrams and flowchart illustrations, respectively, may be implemented in part by computer program instructions, e.g., as logical steps or operations executing on a processor in a computing system. These computer program instructions may be loaded onto a computer, such as a special purpose computer or other programmable data processing apparatus to produce a specifically-configured machine, such that the instructions which execute on the computer or other programmable data processing apparatus implement the functions specified in the flowchart block or blocks.

These computer program instructions may also be stored in a computer-readable memory that can direct a computer or other programmable data processing apparatus to function in a particular manner, such that the instructions stored in the computer-readable memory produce an article of manufacture including computer-readable instructions for implementing the functionality specified in the flowchart block or blocks. The computer program instructions may also be loaded onto a computer or other programmable data processing apparatus to cause a series of operational steps to be performed on the computer or other programmable apparatus to produce a computer-implemented process such that the instructions that execute on the computer or other programmable apparatus provide operations for implementing the functions specified in the flowchart block or blocks.

Accordingly, blocks of the block diagrams and flowchart illustrations support various combinations for performing the specified functions, combinations of operations for performing the specified functions and program instructions for performing the specified functions. It should also be understood that each block of the block diagrams and flowchart illustrations, and combinations of blocks in the block diagrams and flowchart illustrations, could be implemented by special purpose hardware-based computer systems that perform the specified functions or operations, or combinations of special purpose hardware and computer instructions.

In some embodiments, one such special purpose computer includes computer 210. Computer 210 includes a processor 220 configured to executed program code, such as the CAD software 204 and/or machine build software 214. While a single processor can be employed, as one of ordinary skill in the art will recognize, the computer 210 and/or additive manufacturing machine 222 may comprise multiple processors operating in conjunction with one another to perform the functionality described herein. In addition to the memory (e.g., computer readable storage media), which is implemented in some embodiments as data store 206, the processor 220 can also be connected to at least one interface or other means for displaying, transmitting and/or receiving data, content or the like. In this regard, the interface(s) can include at least one communication interface 218 or other means for transmitting and/or receiving data, content or the like, as well as at least one user interface 224 that can include a display and/or a user input interface. The user input interface, in turn, can comprise any of a number of devices allowing the entity to receive data from a user, such as a keypad, a touch display, a joystick or other input device.

The communication interface 218 in some embodiments is configured to transmit and/or receive data, content or the like from other devices via one or more networks 228. According to various embodiments, the one or more networks 228 may be capable of supporting communication in accordance with any one or more of a number of cellular protocols, including second-generation (2G), 2.5G, third-generation (3G), fourth-generation (4G) mobile communication protocols, or the like, as well as other techniques such as, for example, radio frequency (RF), Bluetooth™, infrared (IrDA), or any of a number of different wired or wireless networking techniques, including a wired or wireless Personal Area Network (“PAN”), Local Area Network (“LAN”), Metropolitan Area Network (“MAN”), Wide Area Network (“WAN”), or the like. Although the computer 210, the server 230, and the mobile device 234 are illustrated in FIG. 9 as communicating with one another over the same network, these devices may likewise communicate over multiple, separate networks.

According to various embodiments, many individual steps of a process may or may not be carried out utilizing the computer systems and/or servers described herein, and the degree of computer implementation may vary, as may be desirable and/or beneficial for one or more particular applications.

The present application may include references to directions, such as “forward,” “rearward,” “front,” “rear,” “upward,” “downward,” “top,” “bottom,” “right hand,” “left hand,” “lateral,” “medial,” “distal,” “proximal,” “in,” “out,” “extended,” etc. These references, and other similar references in the present application, are only to assist in helping describe and to understand the particular embodiment and are not intended to limit the present disclosure to these directions or locations.

The present application may also reference quantities and numbers. Unless specifically stated, such quantities and numbers are not to be considered restrictive, but exemplary of the possible quantities or numbers associated with the present application. Also in this regard, the present application may use the term “plurality” to reference a quantity or number. In this regard, the term “plurality” is meant to be any number that is more than one, for example, two, three, four, five, etc. The terms “about,” “approximately,” “near,” etc., mean plus or minus 5% of the stated value. For the purposes of the present disclosure, the phrase “at least one of A, B, and C,” for example, means (A), (B), (C), (A and B), (A and C), (B and C), or (A, B, and C), including all further possible permutations when greater than three elements are listed.

The principles, representative embodiments, and modes of operation of the present disclosure have been described in the foregoing description. However, aspects of the present disclosure which are intended to be protected are not to be construed as limited to the particular embodiments disclosed. Further, the embodiments described herein are to be regarded as illustrative rather than restrictive. It will be appreciated that variations and changes may be made by others, and equivalents employed, without departing from the spirit of the present disclosure. Accordingly, it is expressly intended that all such variations, changes, and equivalents fall within the spirit and scope of the present disclosure, as claimed.

1. An additive manufactured electrical conduit, comprising:
a printed conduit body comprised of two or more body sections;
two or more passageways extending through at least one of the two or more body sections, the two or more passageways being separated within the body by at least one partition, wherein the at least one partition exhibits electrical shielding properties.

2. The electrical conduit of claim 1, further comprising a metal coating layer disposed on the at least one partition, the metal coating layer configured to exhibit electrical shielding properties.

3. The electrical conduit of claim 1, wherein the two or more body sections are rigid, and include a first body section and a second body section.

4. The electrical conduit of claim 3, wherein the first body section is disposed at a non-standard angle with respect to the second body section.

5. The electrical conduit of claim 4, wherein the non-standard angle does not form a planar 2-dimensional bend, and wherein physical deformation is not present at a junction between the first body section and the second body section.

6. The electrical conduit of claim 4, wherein the non-standard angle is not 15 degrees or a multiple of 15 degrees.

7. The electrical conduit of claim 1, wherein the two or more body sections are integrally formed and include a first body section and a second body section, wherein the first body section has a length, and wherein the first body section has a cross-section that varies in shape and/or size along said length.

8. The electrical conduit of claim 1, wherein at least one of the two or more passageways has a cross-section that varies in shape and/or size along a length thereof.

9. The electrical conduit of claim 1, further comprising first and second rib members spaced apart and extending along a portion of either the first section or the second section.

10. The electrical conduit of claim 1, further comprising a power wire routed through one of the two or more passageways, the power wire configured to carry a power signal, and a sensor wire routed through the other one of the two or more passageways, the sensor wire configured to carry a sensed signal.

11. A method of making an electrical conduit of an electrical harness system, the method comprising:
obtaining digital data representative of the electrical conduit according to claim 1;
using the digital data to fabricate the electrical conduit from a first material by a solid freeform fabrication process.

12. The method of claim 11, wherein the solid freeform fabrication process is Fused Deposition Modeling and the first material includes PEKK.

13. The method of claim 11, wherein the method further comprises
plating at least a portion of the at least one partition with an electrically shielding material.

14. The method of claim 13, wherein the electrically shielding material includes nickel, zinc or copper.

15. The method of claim 13, further comprising
routing a power wire through one of the two or more passageways, the power wire configured to carry a power signal; and
routing a sensor wire through the other one of the two or more passageways, the sensor wire configured to carry a sensed signal.

16. (canceled)

17. The method of claim 16, wherein the digital data is further representative of at least one attachment structure selected from a group consisting of:
one or more attachment lugs; and
first and second rib members spaced apart and extending traverse along a portion of the body.

18. The method of claim 11, wherein the digital data is further representative of the body having first and second sections, and wherein the first section is disposed at a non-standard angle with respect to the second section.

19. The method of claim 18, wherein the non-standard angle includes angles that are not a multiple of 15 degrees.

20. (canceled)

21. The electrical conduit of claim 1, wherein the two or more body sections include a first body section and a second body section, wherein one of the first or second body sections has a cross section that is crescent shaped.

22. A solid freeform fabricated electrical conduit, comprising:
a printed thermoplastic conduit body comprised of two or more body sections;
two or more passageways extending through at least one of the two or more body sections, the two or more passageways being separated within the body by at least one partition,
wherein the at least one partition exhibits electrical shielding properties.
